(19) United States
(12) Patent Application Publication
(10) Pub. No.: US 2026/0129937 A1
(43) Pub. Date: May 7, 2026

(54) SEMICONDUCTOR DEVICE AND METHOD FOR FORMING THE SAME

(71) Applicant: TAIWAN SEMICONDUCTOR MANUFACTURING COMPANY, LTD., Hsinchu (TW)

(72) Inventors: Wei-Yip LOH, Hsinchu City (TW); Chun-Hsien HUANG, Hsinchu City (TW); Ting-Hsuan LAI, New Taipei City (TW)

(73) Assignee: TAIWAN SEMICONDUCTOR MANUFACTURING COMPANY, LTD., Hsinchu (TW)

(21) Appl. No.: 18/934,631

(22) Filed: Nov. 1, 2024

(51) Int. Cl. H01L 29/66; H01L 27/092; H01L 29/06; H01L 29/417; H01L 29/423; H01L 29/775; H01L 29/786

(52) U.S. Cl. CPC H10D 64/021; H10D 30/014; H10D 30/6729; H10D 30/6735; H10D 30/43; H10D 30/6757; H10D 62/121; H10D 84/85

(57) ABSTRACT

A semiconductor device includes a first transistor and a second transistor. The first transistor includes a first semiconductor layer, a first source/drain structure in contact with on end of the first semiconductor layer, and a first gate structure wrapping around the first semiconductor layer. The second transistor includes a second semiconductor layer, a second source/drain structure in contact with on end of the second semiconductor layer, and a second gate structure wrapping around the second semiconductor layer. A contact plug electrically connects the first source/drain structure and the second source/drain structure, in which the contact plug comprises a top portion and a bottom portion extending downward from a bottom surface of the top portion. A dual-layer spacer structure is along a sidewall of the top portion of the contact plug. A single-layer spacer structure is along a sidewall of the bottom portion of the contact plug.

### BACKGROUND

The semiconductor integrated circuit (IC) industry has experienced rapid growth. Technological advances in IC materials and design have produced generations of ICs. Each generation has smaller and more complex circuits than the previous generation. However, these advances have increased the complexity of processing and manufacturing ICs. In the course of IC evolution, functional density (i.e., the number of interconnected devices per chip area) has generally increased while geometric size (i.e., the smallest component (or line) that can be created using a fabrication process) has decreased. This scaling-down process generally provides benefits by increasing production efficiency and lowering associated costs. However, since feature sizes continue to decrease, fabrication processes continue to become more difficult to perform. Therefore, it is a challenge to form reliable semiconductor devices at smaller and smaller sizes.

As the semiconductor industry further progresses into technology process nodes in pursuit of higher device density, higher performance, and lower costs, challenges from both fabrication and design issues have led to stacked device structure configurations, such as complementary field effect transistors (C-FET) where an n-type multi-gate transistor and a p-type multi-gate transistor are stacked vertically, one over the other. While existing C-FET structures are generally adequate, they are not satisfactory in all aspects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a perspective view of a semiconductor device in accordance with some embodiments of the present disclosure.

FIGS. 2A to 15 illustrate a method in various stages of forming a semiconductor device in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

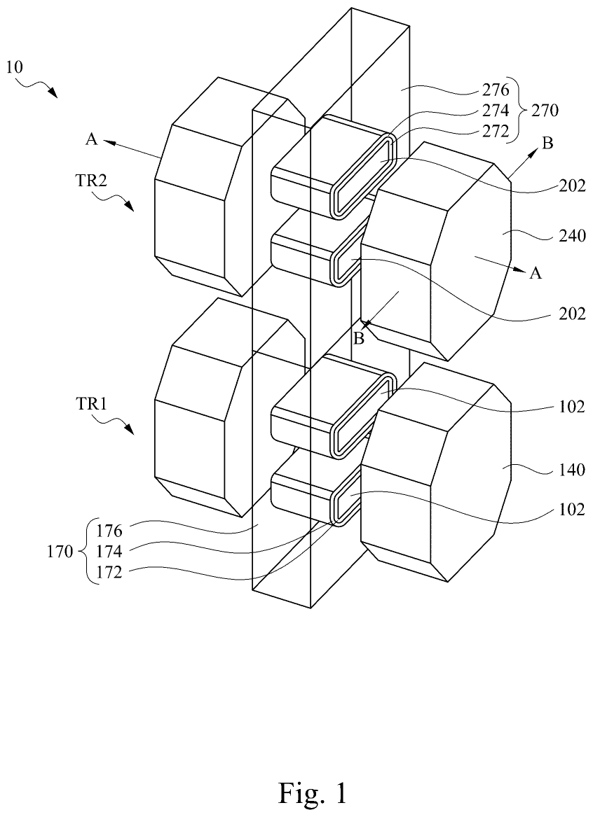

FIG. 1 is a perspective view of a semiconductor device in accordance with some embodiments of the present disclosure. In the present disclosure, a complementary FET (CFET) 10 is provided, and its manufacturing method will be disclosed in the following discussion. In a CFET 10, a first transistor TR1 is disposed over a substrate (not shown), and a second transistor TR2 is disposed vertically above the first transistor TR1. In some embodiments, the first transistor TR1 and the second transistor TR2 may be field effect transistor (FET) and may both include gate-all-around (GAA) configuration, and thus the first transistor TR1 and the second transistor TR2 can also be referred to as GAA FETs. The first transistor TR1 includes first semiconductor channel layers 102 vertically stacked one above another, a first metal gate structure 170 wrapping around each of the first semiconductor channel layers 102, and first source/drain epitaxy structures 140 on opposite ends of each of the first semiconductor channel layers 102. Similarly, the second transistor TR2 includes second semiconductor channel layers 202 vertically stacked one above another, a second metal gate structure 270 wrapping around each of the second semiconductor channel layers 202, and second source/drain epitaxy structures 240 on opposite ends of each of the second semiconductor channel layers 202. The first metal gate structure 170 may include an interfacial layer 172, a gate dielectric layer 174, and a gate electrode 176. Similarly, the second metal gate structure 270 may include an interfacial layer 272, a gate dielectric layer 274, and a gate electrode 276. In some embodiments, the first transistor TR1 has a first conductivity type and the second transistor TR2 has a second conductivity type different from the first conductivity type. For example, the first transistor TR1 is a P-type transistor, and the second transistor TR2 is an N-type transistor. Alternatively, the first transistor TR1 is an N-type transistor, and the second transistor TR2 is P-type transistor.

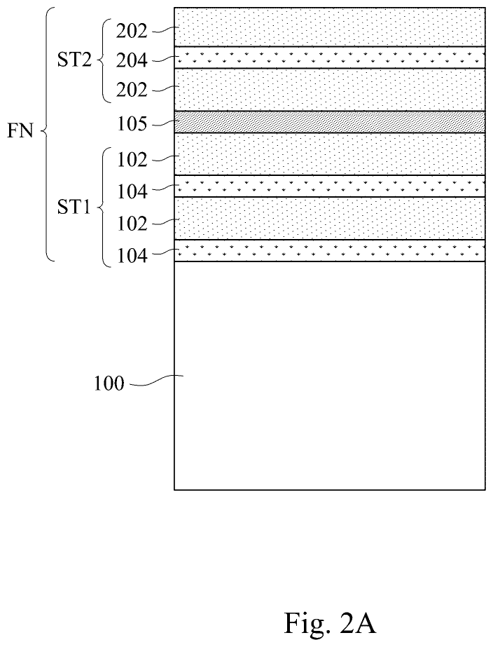

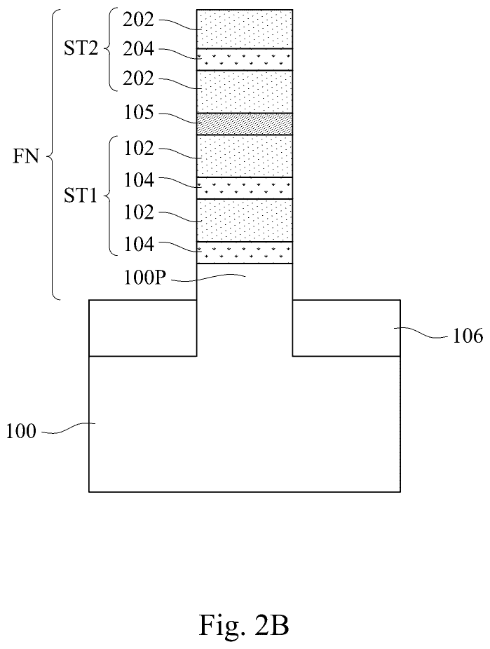

FIGS. 2A to 15 illustrate a method in various stages of forming a semiconductor device in accordance with some embodiments of the present disclosure. It is noted that FIGS. 2A, 3A, 4A, 5A, 6A, and 7A include cross-sectional views the same as the cross-sectional view taken along line A-A of FIG. 1, and FIGS. 2B, 3B, 4B, 5B, 6B, 7B, 8, 9, 10, 11, 12, 13, 14, and 15 include cross-sectional views the same as the cross-sectional view taken along line B-B of FIG. 1. The line A-A may be substantially perpendicular to the line B-B. Although FIGS. 2A to 15 are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part. It is noted that some elements of FIGS. 2A to 15 may be similar to those described with respect to FIG. 1, and thus relevant details will not be repeated for brevity.

Reference is made to FIGS. 2A and 2B. Shown there is a substrate 100. Generally, the substrate 100 may include a bulk semiconductor substrate or a silicon-on-insulator (SOI) substrate. An SOI substrate includes an insulator layer below a thin semiconductor layer that is the active layer of the SOI substrate. The semiconductor of the active layer and the bulk semiconductor generally include the crystalline semiconductor material silicon, but may include one or more other semiconductor materials such as germanium, silicon-germanium alloys, compound semiconductors (e.g., GaAs, AlAs, InAs, GaN, AlN, and the like), or their alloys (e.g., GaₓAl₁₋ₓAs, GaₓAl₁₋ₓN, InₓGa₁₋ₓAs and the like), oxide semiconductors (e.g., ZnO, SnO₂, TiO₂, Ga₂O₃, and the like) or combinations thereof. The semiconductor materials may be doped or undoped. Other substrates that may be used include multi-layered substrates, gradient substrates, or hybrid orientation substrates.

A fin structure FN is formed over the substrate 100. The fin structure FN includes a semiconductor strip 100P, a first stack ST1 of alternating semiconductor layers 102 and 104, a semiconductor layer 105 disposed over the first stack ST1, and a second stack ST2 of alternating semiconductor layers 202 and 204 over the semiconductor layer 105. In some embodiments, the semiconductor layers 102 and 202 may be made of pure silicon layers that are free of germanium. The semiconductor layers 102 and 202 may also be substantially pure silicon layers, for example, with a germanium percentage lower than about 1 percent. The semiconductor layers 104, 105, and 204 may be made of silicon germanium, while the semiconductor layer 105 may include a higher germanium composition than the semiconductor layers 104 and 204. For example, the germanium percentage (atomic percentage concentration) of the semiconductor layer 105 is in a range from about 40 percent and about 60 percent, and the germanium percentage (atomic percentage concentration) of the semiconductor layers 104 and 204 is in a range from about 20 percent and about 40 percent. In some embodiments, the semiconductor layers 102, 104, 105, 202, and 204 may be deposited using suitable deposition process, such as selective epitaxial growth (SEG), chemical vapor deposition (CVD), molecular beam epitaxy (MBE), or other suitable process(es). In some embodiments, the semiconductor layers 104 and 204 may be removed during a replacement gate (RPG) process, and thus the semiconductor layers 104 and 204 can also be referred to as sacrificial layers.

After the fin structure FN is formed, isolation structures 106 are formed over the substrate 100 and laterally surrounding the fin structure FN. In some embodiments, the isolation structures 106 may be in contact with sidewalls of the semiconductor strip 100P of the substrate 100. The isolation structures 106 may be shallow trench isolation (STI) structures, suitable isolation structures, combinations of the foregoing, or the like. In some embodiments, the isolation structures 106 may be made of oxide (e.g., silicon oxide), nitride (e.g., silicon nitride), or combinations thereof.

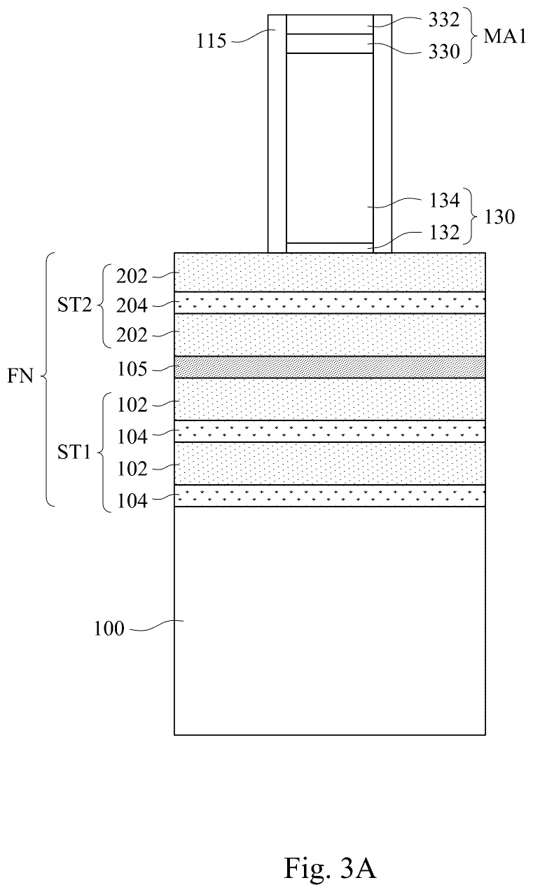

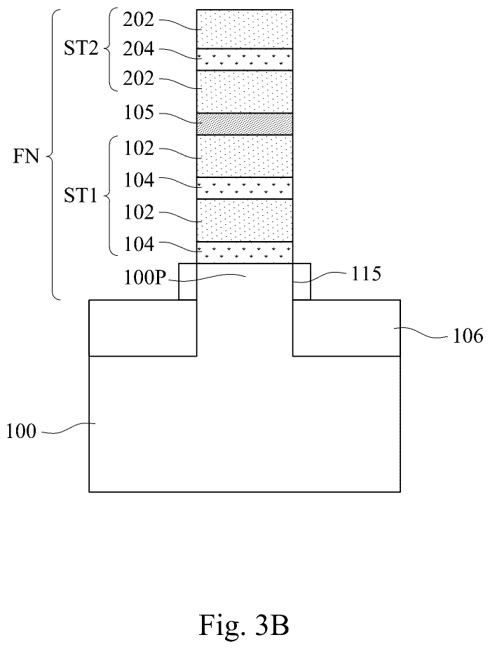

Reference is made to FIGS. 3A and 3B. A dummy gate structure 130 is formed over the substrate 100 and crossing the fin structure FN. In some embodiments, the dummy gate structure 130 includes a dummy gate dielectric 132 and a dummy gate electrode 134 over the dummy gate dielectric 132. The dummy gate dielectric 132 may be, for example, silicon oxide, silicon nitride, a combination thereof, or the like, and may be deposited or thermally grown according to acceptable techniques. The dummy gate electrode 134 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals.

The dummy gate electrode 134 and the dummy gate dielectric 132 may be formed by, for example, depositing a dummy dielectric layer and a dummy gate layer over the substrate 100, forming a patterned mask MA1 over the dummy gate layer, and then performing an etching process to the dummy dielectric layer and the dummy gate layer by using the patterned mask MA1 as etch mask. In some embodiments, the dummy gate electrode 134 may be deposited by physical vapor deposition (PVD), chemical vapor deposition (CVD), sputter deposition, or other techniques for depositing the selected material. In some embodiments, the dummy gate dielectric 132 may be formed by thermal oxidation.

In some embodiments, the patterned mask MA1 includes a first hard mask 330 and a second hard mask 332 over the first hard mask 330. The first hard mask 330 and the second hard mask 332 may be made of different materials. In some embodiments, the first hard mask 330 may be formed of silicon nitride, and the second hard mask 332 may be formed of silicon oxide.

Spacers 115 are formed on opposite sidewalls of the dummy gate structure 130 and on opposite sidewalls of the fin structure FN. In some embodiments, the spacers 115 may be formed of silicon oxide, silicon nitride, silicon oxynitride, combinations thereof. In some embodiments, the spacers 115 may be formed by, for example, depositing a spacer layer blanket over the substrate, and then performing an anisotropic etching process to remove horizontal portions of the spacer layer, such that vertical portions of the spacer layer remain on sidewalls of the dummy gate structure 130 and on sidewalls of the fin structure FN. In some embodiments, portions of the spacers 115 on sidewalls of the dummy gate structures 130 can be referred to as gate spacers, and the portions of the spacers 115 on sidewalls of the fin structure FN can be referred to as fin spacers. In some embodiments, the spacer layer may be deposited using techniques such CVD, ALD, or the like.

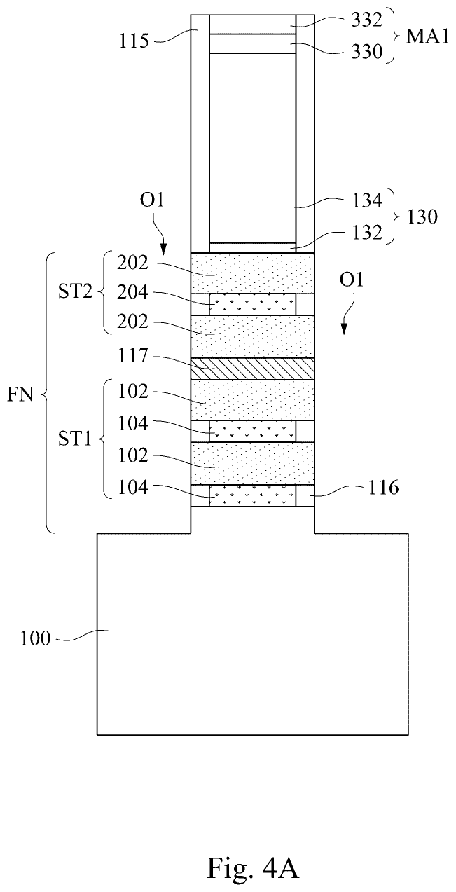

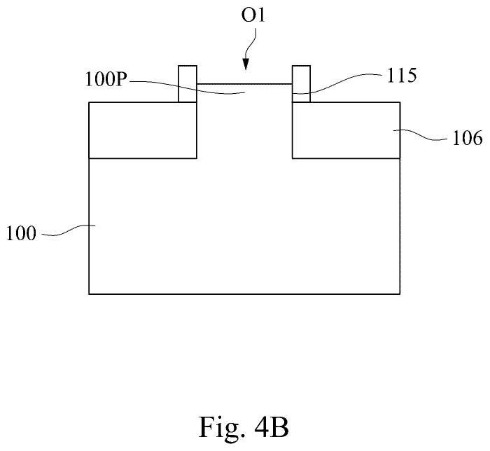

Reference is made to FIGS. 4A and 4B. An etching process is performed to remove portions of the fin structure FN by using the dummy gate structure 130 and the gate spacers 115 as etch mask, so as to form source/drain openings O1 in the fin structure FN. In some embodiments, the etching process may be wet etch, dry etch, or combinations thereof.

After the source/drain openings O1 are formed, inner spacers 116 are formed on opposite ends of each of the semiconductor layers 104 and 204, and the semiconductor layer 105 is replaced with an isolation layer 117. The inner spacers 116 may be deposited by a conformal deposition process, such as CVD, ALD, or the like. The inner spacer layer may include a material such as SiN, SiOCN, SiCN, SIOC, although any suitable material, such as low-dielectric constant (low-k) materials having a k-value less than about 3.5, may be utilized.

The inner spacers 116 and the isolation layer 117 can be formed by, for example, performing an etching process to laterally etch the semiconductor layers 104 and 204 to form sidewall recesses, and to remove the semiconductor layer 105 to form a gap. In some embodiments, the sidewalls of the semiconductor layers 104, 105, and 204 may be etched using isotropic etching processes, such as wet etching or the like. In some embodiments where the semiconductor layers 104, 105, and 204 include, e.g., SiGe, and the semiconductor layers 102 and 202 include, e.g., Si, an etch process with tetramethylammonium hydroxide (TMAH), ammonium hydroxide (NH₄OH), or the like may be used to etch sidewalls of the semiconductor layers 104, 105, and 204. In some embodiments, because the semiconductor layer 105 may include different germanium concentration than the semiconductor layers 104 and 204, the etchant of the etching process may be selected such that the etching process includes a higher etch rate to the semiconductor layer 105 than to the semiconductor layers 104 and 204. As a result, the semiconductor layer 105 can be removed, while the semiconductor layers 104 and 204 are slightly etched to form the sidewall recesses. Then, inner spacers 116 are formed in the sidewall recesses on opposite ends of each of the semiconductor layers 104 and 204, and the isolation layer 117 is formed in the gap. In some embodiments, the inner spacers 116 and the isolation layer 117 may be formed by, for example, depositing a dielectric material blanket over the substrate 100 and filling the sidewall recesses and the gap, and then performing an anisotropic etching to remove portions of the dielectric material outside the sidewall recesses and the gap, leaving the remaining portions of the dielectric material in the sidewall recesses and the gap as the inner spacers 116 and the isolation layer 117, respectively.

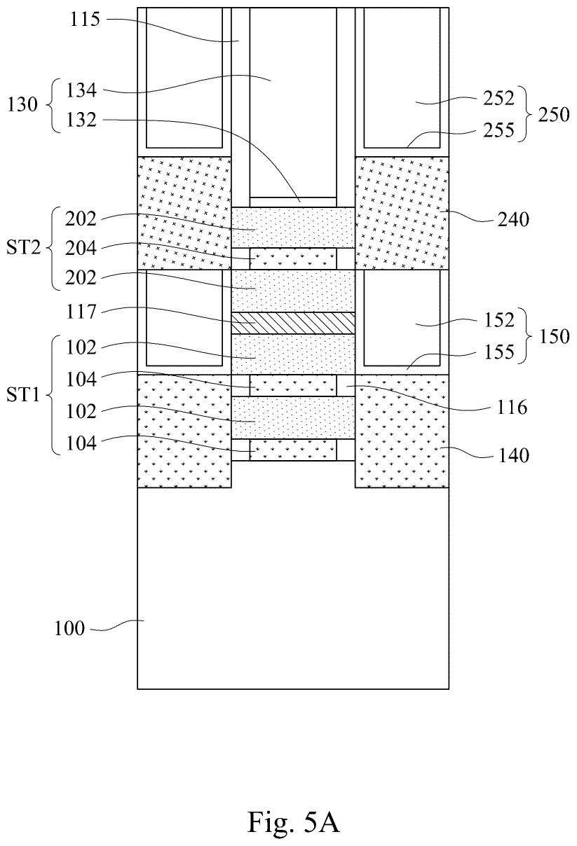

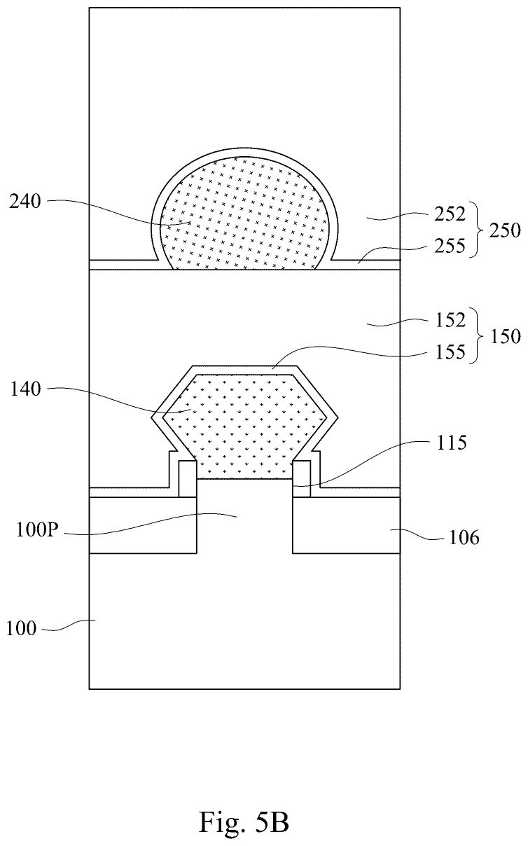

Reference is made to FIGS. 5A and 5B. First source/drain epitaxy structures 140 are formed on opposite ends of the exposed semiconductor layer 102. In some embodiments, the first source/drain epitaxy structures 140 may include semiconductor material, such as silicon germanium (SiGe), or other suitable semiconductor material. In some embodiments, the first source/drain epitaxy structures 140 may be formed by a selective epitaxial growth (SEG) process. The SEG process may selectively grow a semiconductor material on exposed semiconductor surfaces, such as the exposed surfaces of the semiconductor layer 102. In some embodiments, during forming the first source/drain epitaxy structures 140, a protective layer may be formed covering the semiconductor layers 202, such that the SEG process would not grow a semiconductor material from surfaces of the semiconductor layers 202. In some embodiments, the first source/drain epitaxy structures 140 may be doped with p-type dopants, such as boron (B), gallium (Ga), indium (In), aluminium (Al), or the like. In other embodiments, the first source/drain epitaxy structures 140 may be doped with n-type dopants, such as n-type dopants, such as phosphorus (P), arsenic (As), or antimony (Sb), or the like.

A contact etch stop layer (CESL) 155 is formed covering the first source/drain epitaxy structures 140. Afterwards, an interlayer dielectric (ILD) layer 152 is formed over the CESL 155. Then, an etching back process is performed to lower top surfaces of the CESL 155 and the ILD layer 152 to a position, such that at least the topmost one of the semiconductor layers 202 are exposed through the source/drain openings O1. In some embodiments, the CESL 155 and the ILD layer 152 can be collectively referred to as an isolation structure 150. In some embodiments, the topmost one of the semiconductor layers 102 and the bottommost one of the semiconductor layers 202 may be covered by the isolation structure 150.

In some embodiments, the CESL 155 may be a dielectric layer including silicon nitride, silicon oxynitride or other suitable materials. In some embodiments, the ILD layer 152 may include silicon oxide, silicon nitride, silicon oxynitride, tetraethoxysilane (TEOS), phosphosilicate glass (PSG), borophosphosilicate glass (BPSG), low-k dielectric material, and/or other suitable dielectric materials. Examples of low-k dielectric materials include, but are not limited to, fluorinated silica glass (FSG), carbon doped silicon oxide, amorphous fluorinated carbon, parylene, bis-benzocyclobutenes (BCB), or polyimide. The CESL 155 and the ILD layer 152 can be formed using, for example, CVD, ALD or other suitable techniques.

Second source/drain epitaxy structures 240 are formed on opposite ends of the exposed semiconductor layer 202. In some embodiments, the second source/drain epitaxy structures 240 may be formed by a selective epitaxial growth (SEG) process. The SEG process may selectively grow a semiconductor material on exposed semiconductor surfaces, such as the exposed surfaces of the exposed semiconductor layer 202. In some embodiments, the second source/drain epitaxy structures 240 may be doped with n-type dopants, such as phosphorus (P), arsenic (As), or antimony (Sb), or the like.

A contact etch stop layer (CESL) 255 is formed covering the second source/drain epitaxy structures 240. Afterwards, an interlayer dielectric (ILD) layer 252 is formed over the CESL 255. Then, a planarization process, such as CMP, is performed to remove excess materials of the CESL 255 and the ILD layer 252 until the dummy gate structure 130 is exposed. In some embodiments, the patterned masks MA1 are removed during the planarization process. In some embodiments, the CESL 255 and the ILD layer 252 can be collectively referred to as an isolation structure 250. The materials of the CESL 255 and the ILD layer 252 may be similar to the materials of the CESL 155 and the ILD layer 152, respectively, and thus relevant details will not be repeated for brevity.

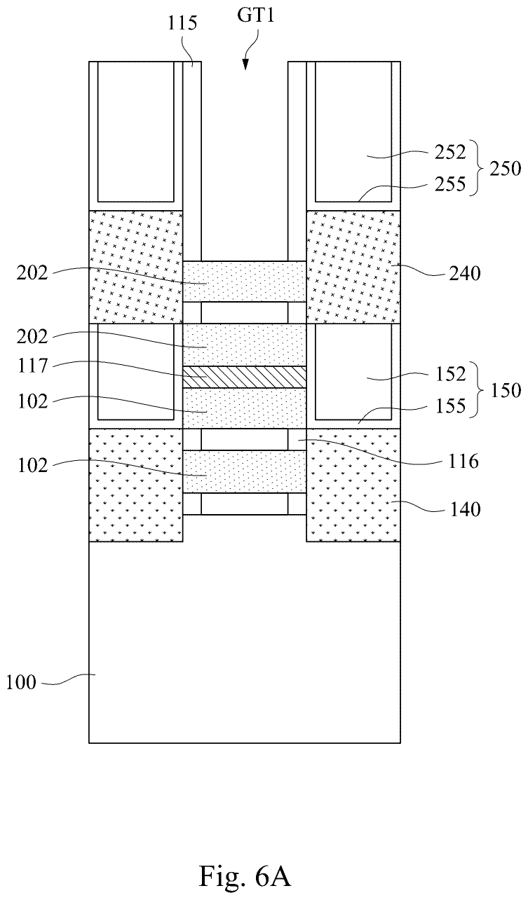

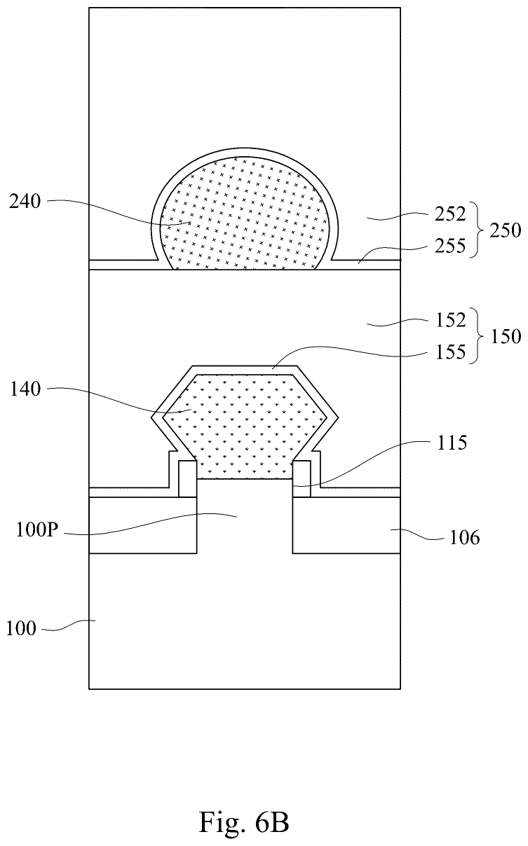

Reference is made to FIGS. 6A and 6B. The dummy gate structure 130 is removed to form gate trench GT1 between the gate spacers 115. Then, an etching process is performed to remove the semiconductor layers 104 and 204, such that at least the topmost one of the semiconductor layers 202 and at least the bottommost one of the semiconductor layers 102 are suspended over the substrate 100.

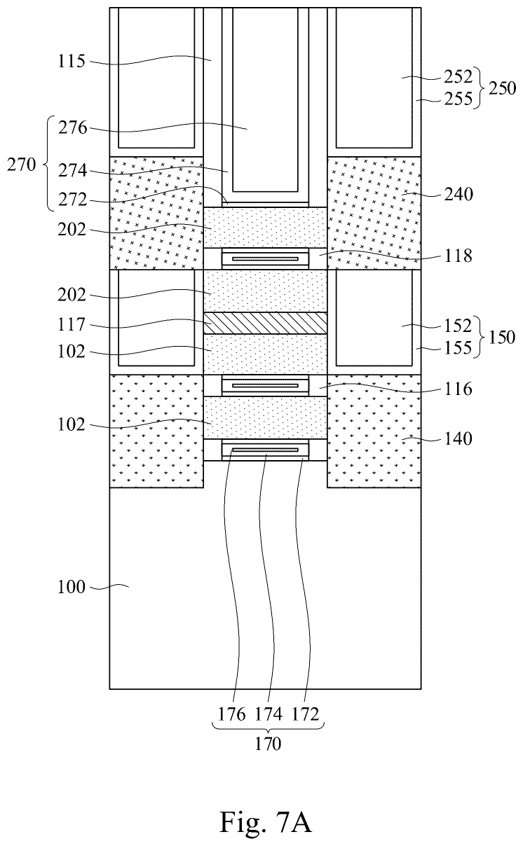

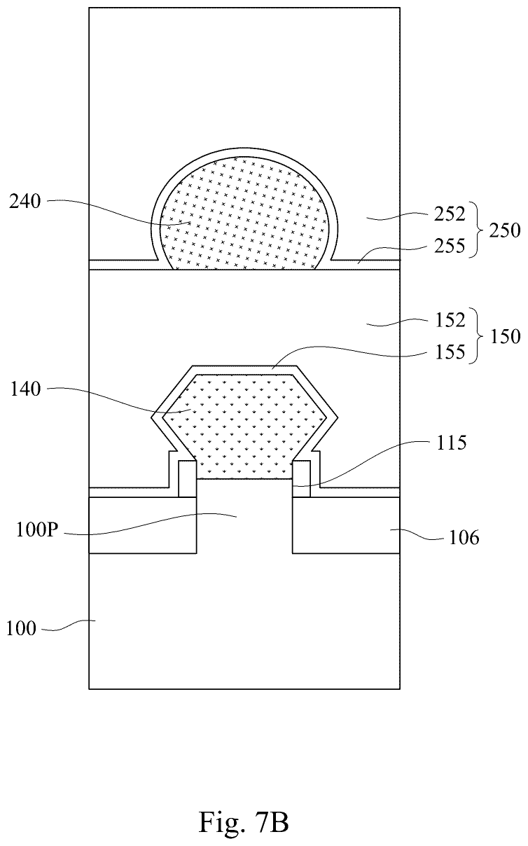

Reference is made to FIGS. 7A and 7B. Interfacial layers 172 and 272 are formed on exposed surfaces of the semiconductor layers 102 and 202, respectively. Then, gate dielectric layers 174 and 274 are formed over the interfacial layers 172 and 272, respectively. In some embodiments, the interfacial layers 172 and 272 may be formed using a same deposition process, and the gate dielectric layers 174 and 274 may be formed using a same deposition process.

After the interfacial layers 172 and 272 and the gate dielectric layers 174 and 274 are formed, gate electrodes 176 and 276 are formed in the gate trench GT1 and over the gate dielectric layers 174 and 274, respectively. In some embodiments, the gate electrodes 176 and 276 may include a same material or different materials. In the embodiments where the gate electrodes 176 and 276 are made of different materials, the gate electrode 176 is formed in the gate trench GT1, the gate electrode 176 is then etched back, such that the remaining gate electrode 176 is at the lower portion of the gate trench GT1. Afterwards, the gate electrode 276 is then formed in the upper portion of the gate trench GT1 and over the gate dielectric layers 274.

Accordingly, first metal gate structure 170 and second metal gate structure 270 are formed. In greater detail, the first metal gate structure 170 is formed in bottom portion of the gate trench GT1, such that the first metal gate structure 170 may wrap around the respective semiconductor layer 102. The second metal gate structure 270 is formed in upper portion of the gate trench GT1 and above the first metal gate structure 170, such that the second metal gate structure 270 may wrap around the respective semiconductor layer 202. In some embodiments, the first metal gate structure 170 may include the interfacial layer 172, the gate dielectric layer 174 over the interfacial layer 172, and the gate electrode 176 over the gate dielectric layer 174. The second metal gate structure 270 may include the interfacial layer 272, the gate dielectric layer 274 over the interfacial layer 272, and the gate electrode 276 over the gate dielectric layer 274.

In some embodiments, the interfacial layers 172 and 272 may be made of oxide, such as aluminum oxide (Al₂O₃), silicon oxide (SiO₂), or the like. In some embodiments, the gate dielectric layers 174 and 274 may include high-k dielectric. Examples of high-k dielectric material include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-k dielectric materials, and/or combinations thereof.

The gate electrodes 176 and 276 may include work function metal layer(s) and a filling metal. The work function metal layer may be an n-type or p-type work function layer. Exemplary p-type work function metals include TiN, TaN, Ru, Mo, Al, WN, ZrSi₂, MoSi₂, TaSi₂, NiSi₂, WN, other suitable p-type work function materials, or combinations thereof. Exemplary n-type work function metals include Ti, Ag, TaAl, TaAlC, TiAlN, TaC, TaCN, TaSiN, Mn, Zr, other suitable n-type work function materials, or combinations thereof. The work function layer may include a plurality of layers. The filling metal may include tungsten (W), aluminum (Al), copper (Cu), or another suitable conductive material(s).

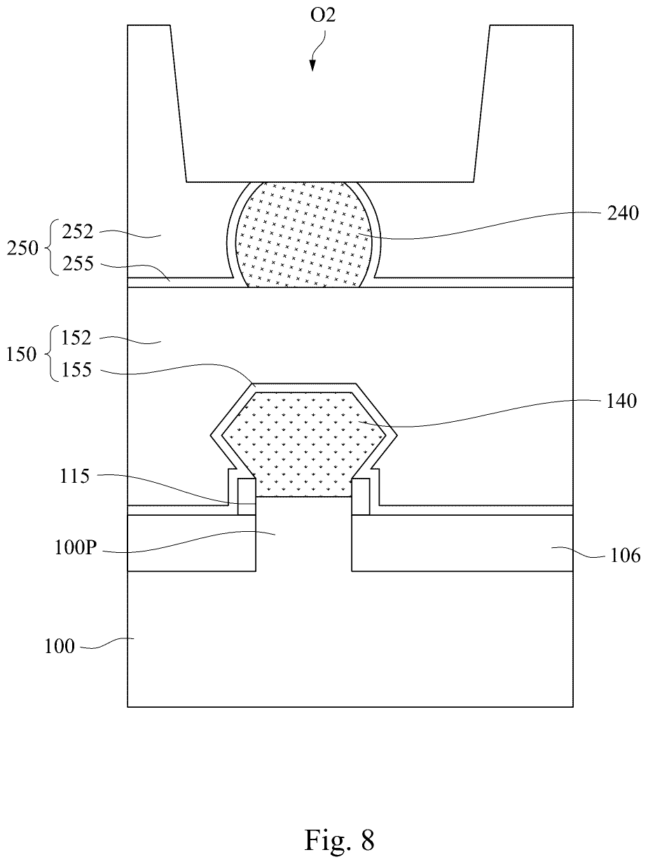

Reference is made to FIG. 8. The isolation structure 250 is patterned to form an opening O2 in the isolation structure 250. In greater detail, portions of the ILD layer 252 and the CESL 255 are removed during the patterning process, such that top surface of the second source/drain epitaxy structure 240 is exposed through the opening O2. In some embodiments, the isolation structure 250 can be patterned, for example, forming a mask layer (not shown) over the substrate 100 and exposing unwanted portion of the isolation structure 250, performing an etching process to remove the unwanted portion of the isolation structure 250 until top surface the second source/drain epitaxy structure 240 is exposed, and then removing the mask layer once the etching process is complete.

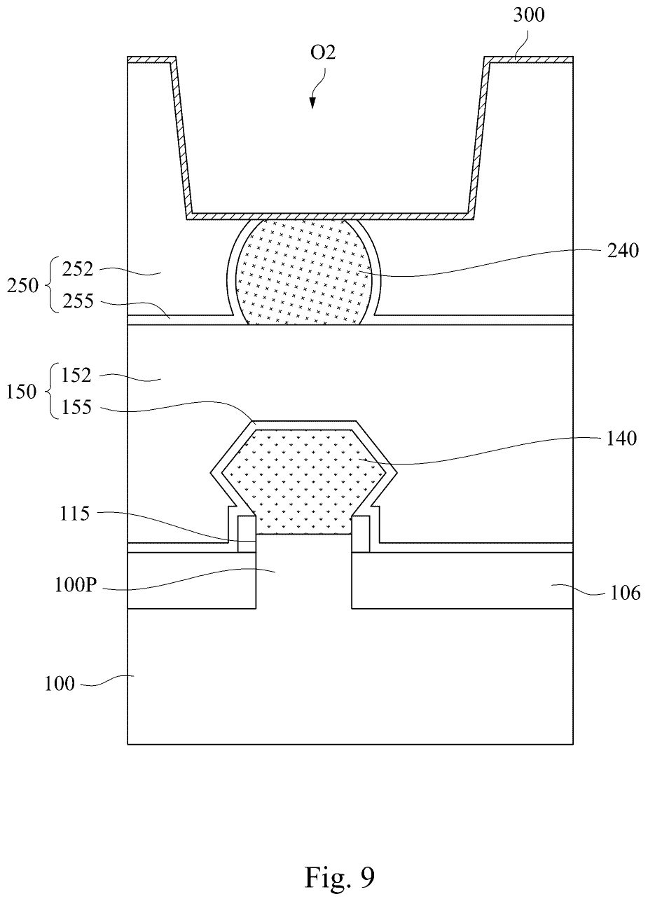

Reference is made to FIG. 9. A spacer layer 300 deposited over the substrate 100 and lining the top surface of the isolation structure 250 and the opening O2 in the isolation structure 250. In greater detail, the spacer layer 300 may line the opposite sidewalls and bottom surface of the opening O2. In some embodiments, the spacer layer 300 may be made of a dielectric material, such as silicon nitride (SiN), silicon oxynitride (SiON), and other carbon-doped low-k dielectrics, such as SiOCN material. The spacer layer 300 may be formed using suitable deposition process, such as physical vapor deposition (PVD), chemical vapor deposition (CVD), atomic layer deposition (ALD), or other suitable deposition process.

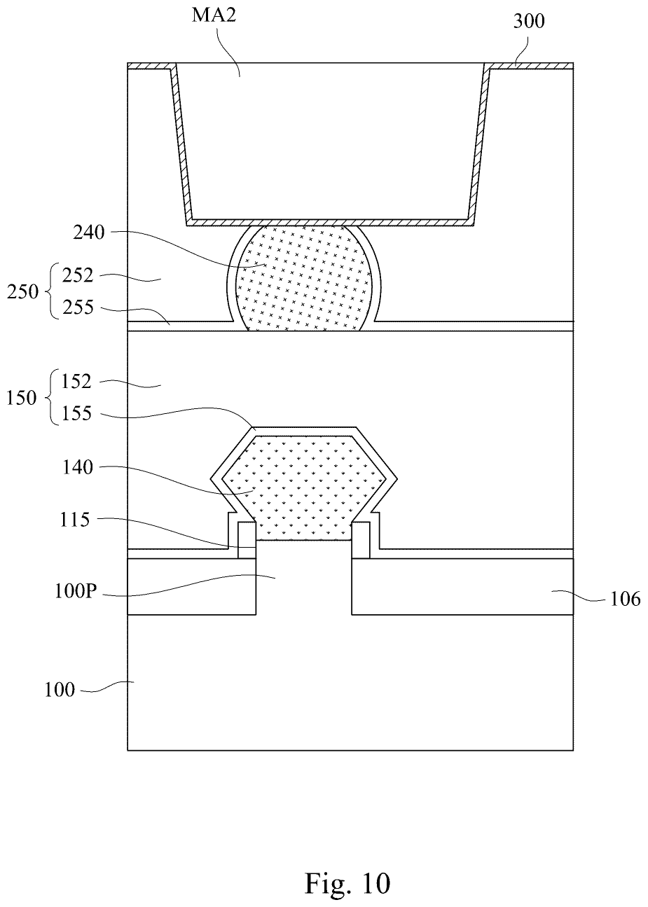

Reference is made to FIG. 10. A mask layer MA2 is formed in the opening O2 of the isolation structure 250 and includes an opening O3. The mask layer MA2 may be a photoresist, and may be formed by, for example, forming a resist layer filling the opening O2 of the isolation structure 250, exposing the resist layer to a pattern, performing post-exposure bake processes, and developing the resist layer to form the mask layer MA2.

An etching process is then performed to remove portions of the isolation structures 250 and 150 until the first source/drain epitaxy structure 140 is exposed. Accordingly, an opening O4 is formed extending through the spacer layer 300, the isolation structure 250 and into the isolation structure 150, in which top surface of the first source/drain epitaxy structure 140 is exposed through the opening O4. In some embodiments, at least a portion of the second source/drain epitaxy structure 240 may also be removed during the etching process, and thus at least a sidewall of the second source/drain epitaxy structure 240 is exposed through the opening O4. In some embodiments, the etching process may include an anisotropic etching process, such as a plasma dry etch.

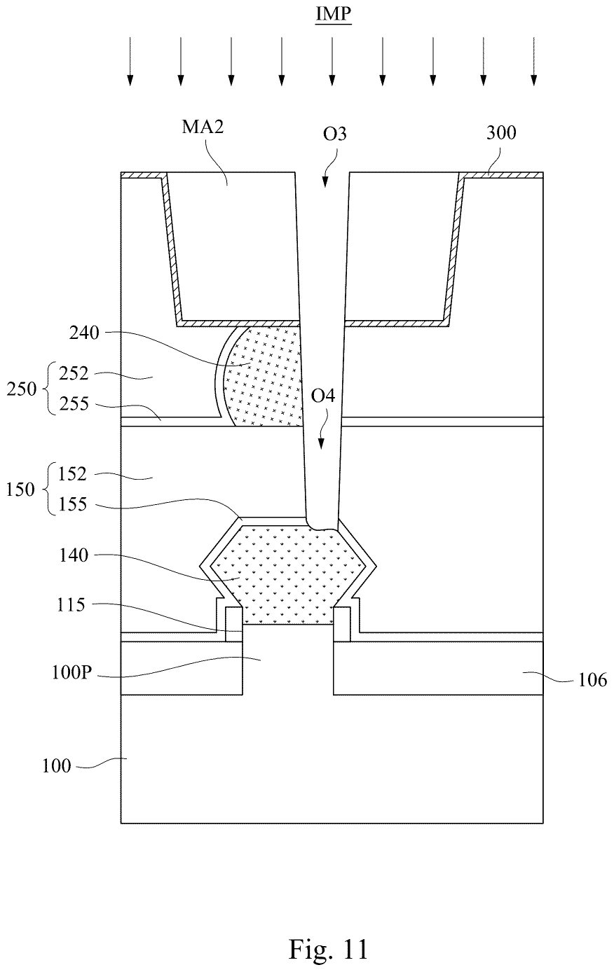

Reference is made to FIG. 11. Once the opening O4 is formed, an ion implantation process IMP may be performed, through the opening O3 of the mask layer MA2 and the opening O4 in the isolation structures 150 and 250, to dope the first source/drain epitaxy structure 140. In some embodiments, when the first source/drain epitaxy structure 140 is a P-type epitaxy structure, P-type dopants may be used in the ion implantation process IMP. On the other hand, when the first source/drain epitaxy structure 140 is n N-type epitaxy structure, N-type dopants may be used in the ion implantation process IMP.

The implantation process IMP may be a directional implantation process. For example, the incident direction of the ions may be substantially perpendicular to the top surface of the substrate 100. Accordingly, the ions can be implanted, vertically through the openings O3 and O4, down to the first source/drain epitaxy structure 140. On the other hand, because the second source/drain epitaxy structure 240 is covered by the mask layer MA2, the mask layer MA2 may protect the second source/drain epitaxy structure 240 from the implantation process IMP. It is noted that although the sidewall of the second source/drain epitaxy structure 240 may be exposed through the opening O4, the exposed sidewall of the second source/drain epitaxy structure 240 is a substantially vertical sidewall, which is parallel to the incident direction of the dopants, and thus the second source/drain epitaxy structure 240 may not be doped or negligible doped during the implantation process IMP.

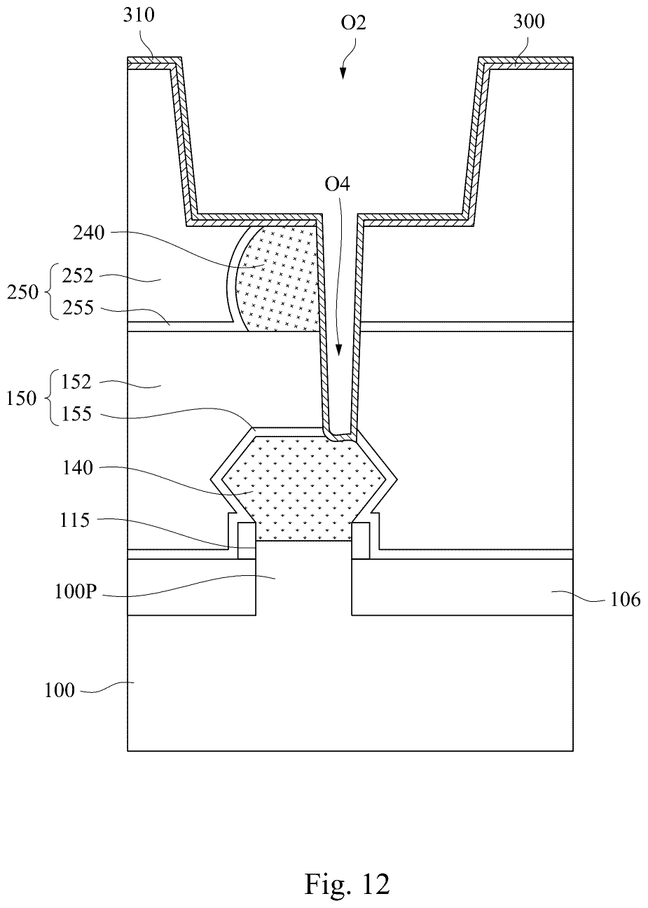

Reference is made to FIG. 12. The mask layer MA2 is removed to reveal the opening O2 in the isolation structure 250. The opening O2 may be spatially connected with the opening O4. In some embodiments, the opening O4 extends downward from the bottom of the opening O2, and may include a narrower width than the opening O2.

Then, a spacer layer 310 is deposited over the 100 and lining the spacer layer 300 in the opening O2 and the opening O4. In greater detail, the spacer layer 310 may line the spacer layer 300 and opposite sidewalls and bottom surface of the opening O4. In some embodiments, the spacer layer 310 may be in contact with the isolation structures 150 and 250, the first source/drain epitaxy structure 140, and the second source/drain epitaxy structure 240. The spacer layer 310 may be thinner than the spacer layer 300, which allows the spacer layer 310 being formed in a relatively narrower opening O4. In some embodiments, the spacer layer 310 may be made of a different material than the spacer layer 300. In other embodiments, the spacer layer 310 may be made of a same material as the spacer layer 300. In some embodiments, the spacer layer 310 may be made of a dielectric material, such as silicon nitride (SiN), silicon oxynitride (SiON), and other carbon-doped low-k dielectrics, such as SiOCN material. The spacer layer 310 may be formed using suitable deposition process, such as physical vapor deposition (PVD), chemical vapor deposition (CVD), atomic layer deposition (ALD), or other suitable deposition process.

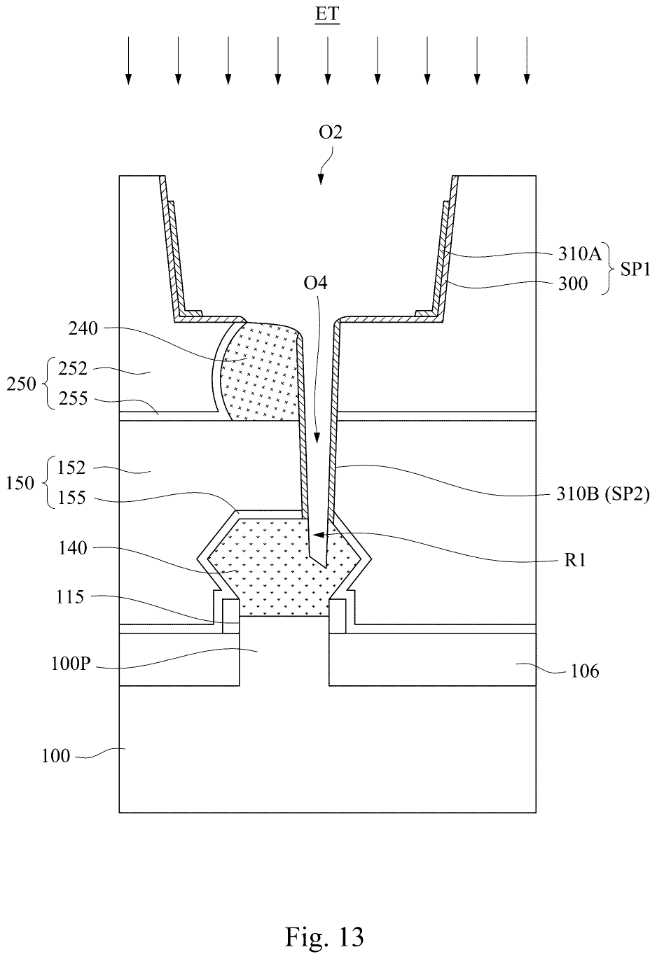

Reference is made to FIG. 13. An etching process ET is performed to remove portions of the spacer layers 300 and 310. In some embodiments, the etching process ET may be a directional etching process, such as a plasma dry etching, in which the etchants (e.g., particles, ions, plasma) may be directed along a certain direction (e.g., the vertical direction). Accordingly, the etching process ET may substantially remove the horizontal portions of the spacer layers 300 and 310, while leaving the vertical portions of the spacer layers 300 and 310 remaining over the substrate 100 once the etching process ET is complete. As a result, the first source/drain epitaxy structure 140 and the second source/drain epitaxy structure 240 may be exposed.

In some embodiments, after the etching process ET is complete, the spacer layer 310 may be divided into a spacer layer 310A lining sidewalls of the opening O2 and a spacer layer 310B lining sidewalls of the opening O4, in which the spacer layer 310A is spaced apart from the spacer layer 310B. The spacer layer 310A and the spacer layer 310 can be collectively referred to as a spacer structure SP1, in which the spacer structure is a multi-layer spacer structure or a dual-layer spacer structure. On other hand, the spacer layer 310B can also be referred to as a single-layer spacer structure SP2. The dual-layer spacer structure SP1 may be thicker than the single-layer spacer structure SP2.

In some embodiments, during the etching process ET, the first source/drain epitaxy structure 140 may also be etched, such that a recess R1 may be formed extending into the first source/drain epitaxy structure 140. However, second source/drain epitaxy structure 240 may not be etched, or may be etched by less material than the first source/drain epitaxy structure 140. This is because prior to performing the etching process ET (see FIG. 12), there is only a single spacer layer 310 covering the top surface of the first source/drain epitaxy structure 140, while there are two spacers (e.g., the spacer layers 300 and 310) covering the top surface of the second source/drain epitaxy structure 240. As a result, once the horizontal portion of the spacer layer 310 are removed, the first source/drain epitaxy structure 140 will be exposed, while the second source/drain epitaxy structure 240 may still be covered by the horizontal portion of the spacer layer 300. As the etching process ET continues to etch the exposed horizontal portion of the spacer layer 300, the exposed first source/drain epitaxy structure 140 will be subject to the etching process ET, resulting in the formation of the recess R1.

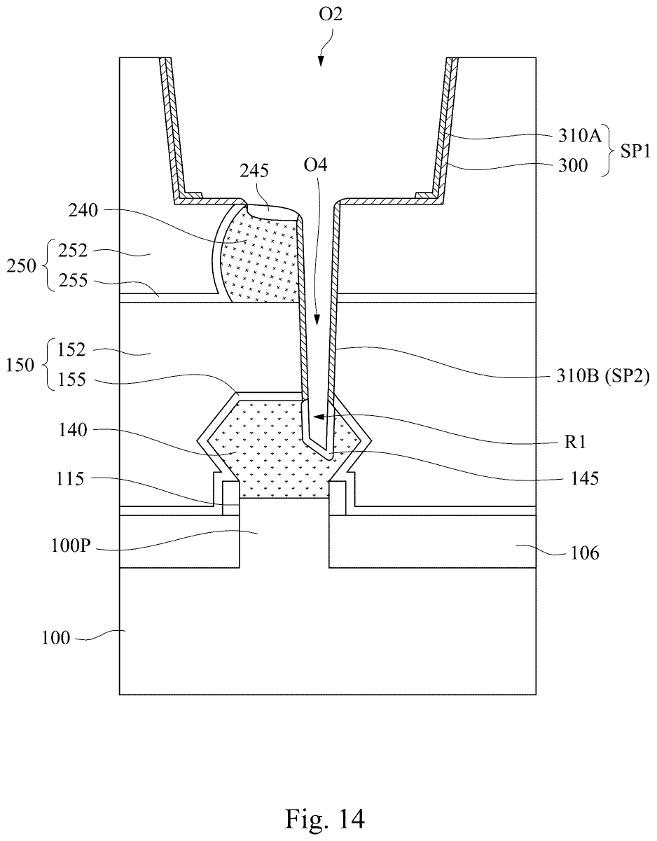

In the embodiments of the present disclosure, by utilizing the spacer layers 300 and 310, the device performance can be improved. For example, the etching process ET as discussed in FIG. 13 may form a recess R1 into the first source/drain epitaxy structure 140, which in turn will increase the exposed surface of the first source/drain epitaxy structure 140, and thus the contact resistance between the first source/drain epitaxy structure 140 and the following formed silicide layer for the following formed silicide layer (e.g., the first silicide layer 145 in FIG. 14) can be reduced. On the other hand, the dual-layer spacer structure SP2 can also protect the second source/drain epitaxy structure 240 from severe material loss during the etching process ET. In some embodiments where the spacer layer 300 is absent, the second source/drain epitaxy structure 240 may be subject to the etching process ET once the spacer layer 310 is removed, and will reduce the volume of the second source/drain epitaxy structure 240. The reduced volume of the second source/drain epitaxy structure 240 will reduce to the exposed surface of the second source/drain epitaxy structure 240. However, with the spacer layer 300, the second source/drain epitaxy structure 240 may keep a sufficient volume and a substantially flat exposed surface for the following formed silicide layer (e.g., the second silicide layer 245 in FIG. 14), which will improve the contact resistance between the second source/drain epitaxy structure 240 and the following formed silicide layer.

Reference is made to FIG. 14. A first silicide layer 145 and a second silicide layer 245 are formed on the first source/drain epitaxy structure 140 and the second source/drain epitaxy structure 240, respectively. In greater detail, the first silicide layer 145 and the second silicide layer 245 are formed selectively on the exposed surfaces of the first source/drain epitaxy structure 140 and the second source/drain epitaxy structure 240. For example, the first silicide layer 145 and the second silicide layer 245 may be formed by, for example, depositing a metal layer into the openings O2 and O4, and then performing an annealing process so that portions of the metal layer may react with the first source/drain epitaxy structure 140 and the second source/drain epitaxy structure 240 to form the first silicide layer 145 and the second silicide layer 245. In some embodiments, the un-reacted portions of the metal layer may then be removed using suitable etching process. In some embodiments, the first silicide layer 145 and the second silicide layer 245 may include titanium silicide (TiSi), titanium disilicide (TiSi₂), molybdenum silicide (MoSi₂), tungsten silicide (WSi₂), tantalum silicide (TaSi₂), or other suitable silicide.

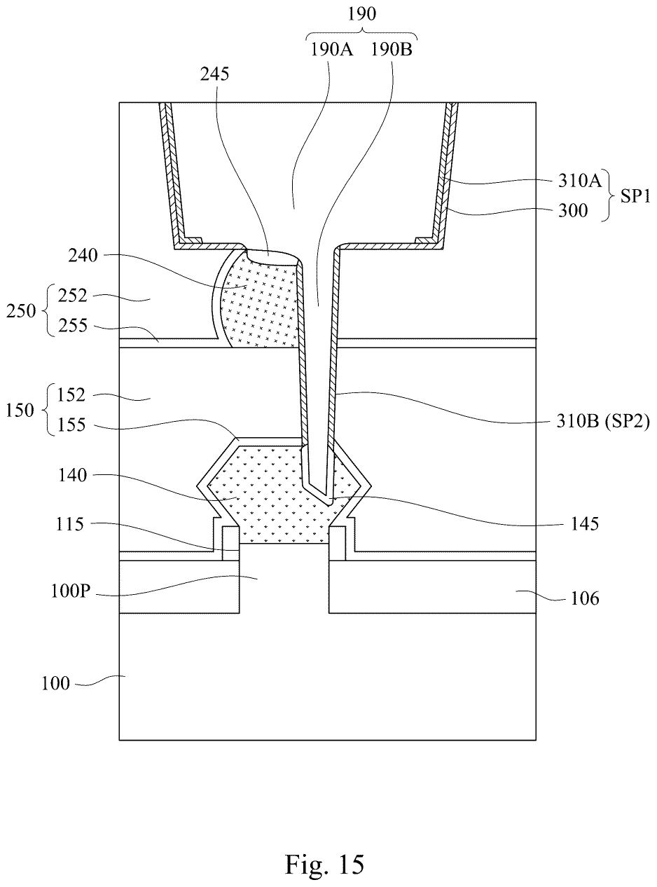

Reference is made to FIG. 15. A contact plug 190 is formed in the openings O2 and O4, and the recess R1. In some embodiments, the contact plugs 190 may be formed by, for example, depositing a conductive material in the contact openings O2, and then performing a planarization process (e.g., CMP) until the isolation structure 250 is exposed. In some embodiments, the conductive material may include one or more layers of Co, Ni, W, Ti, Ta, Cu, Al, TiN, and TaN, combinations thereof, and/or other suitable material. The contact plug 190 is electrically connected with the first source/drain epitaxy structure 140 through the first silicide layer 145, and is electrically connected with the second source/drain epitaxy structure 240 through the first silicide layer 245. Accordingly, the contact plug 190 may electrically connects the first source/drain epitaxy structure 140 and the overlying second source/drain epitaxy structure 240. In some embodiments, the contact plug 190 can also be referred to as source/drain contact.

In some embodiments, the contact plug 190 may include a top portion 190A and a bottom portion 190B extending downward from the bottom surface of the top portion 190A and having a narrower width than the top portion 190A. Here, the top portion 190A may be the portion of the contact plug 190 filled in the opening O2, and the bottom portion 190B may be the portion of the contact plug 190 filled in the opening O4. In some embodiments, the dual-layer spacer structure SP1 may be disposed on opposite sidewalls of the top portion 190A of the contact plug 190. In greater detail, the opposite sidewalls of the top portion 190A of the contact plug 190 may be spaced apart from the spacer layer 300 of the dual-layer spacer structure SP1 though the spacer layer 310A of the dual-layer spacer structure SP1, while the bottom surface of the top portion 190A of the contact plug 190 may be in contact with the spacer layer 300 of the dual-layer spacer structure SP1. In some embodiments, at least a portion of the bottom surface of the bottom portion 190B of the contact plug 190 is in contact with the second silicide layer 245. On the other hand, the single-layer spacer structure SP2 may be disposed on opposite sidewalls of the bottom portion 190B of the contact plug 190. In some embodiments, at least a portion of the opposite sidewalls of the bottom portion 190B of the contact plug 190 is in contact with the first silicide layer 145.

According to the aforementioned embodiments, it can be seen that the present disclosure offers advantages in fabricating integrated circuits. It is understood, however, that other embodiments may offer additional advantages, and not all advantages are necessarily disclosed herein, and that no particular advantage is required for all embodiments. Embodiments of the present disclosure provide a method for forming a CFET. During the formation of the contact opening, a single-layer spacer structure is formed covering a bottom source/drain epitaxy structure of the CFET and a dual-layer spacer structure is formed covering a top source/drain epitaxy structure of the CFET. An etching process is performed to remove the single-layer spacer structure and to form a recess extending into the bottom source/drain epitaxy structure of the CFET, the recess may increase the exposed surface of the bottom source/drain epitaxy structure of the CFET, and will be beneficial to reduce the contact resistance between the bottom source/drain epitaxy structure of the CFET and the following formed bottom silicide layer. On the other hand, during the etching process, the dual-layer spacer structure may protect the top source/drain epitaxy structure of the CFET from material loss, and the top source/drain epitaxy structure of the CFET may keep a sufficient volume and a substantially flat contact area for the following formed silicide layer, which will improve the contact resistance between the top source/drain epitaxy structure and the following formed top silicide layer. With such configuration, the device performance can be improved.

In some embodiments of the present disclosure, a semiconductor device includes a first transistor over a substrate. The first transistor includes a first semiconductor layer, a first source/drain structure in contact with on end of the first semiconductor layer, and a first gate structure wrapping around the first semiconductor layer. A second transistor is vertically stacked above the first transistor. The second transistor includes a second semiconductor layer, a second source/drain structure in contact with on end of the second semiconductor layer, and a second gate structure wrapping around the second semiconductor layer. A contact plug electrically connects the first source/drain structure and the second source/drain structure, in which the contact plug comprises a top portion and a bottom portion extending downward from a bottom surface of the top portion. A dual-layer spacer structure is along a sidewall of the top portion of the contact plug. A single-layer spacer structure is along a sidewall of the bottom portion of the contact plug.

In some embodiments, the dual-layer spacer structure includes a first spacer layer, and a second spacer layer between the first spacer layer and the sidewall of the top portion of the contact plug.

In some embodiments, the second spacer layer and the single-layer spacer structure are made of a same material.

In some embodiments, the first spacer layer is thicker than the second spacer layer.

In some embodiments, the first spacer layer is in contact with the bottom surface of the top portion of the contact plug.

In some embodiments, the dual-layer spacer structure is laterally spaced apart from the single-layer spacer structure.

In some embodiments, the dual-layer spacer structure is thicker than the single-layer spacer structure.

In some embodiments of the present disclosure, a semiconductor device includes a first transistor over a substrate and a second transistor vertically stacked above the first transistor. A contact plug electrically connects a first source/drain structure of the first transistor and a second source/drain structure of the second transistor. The contact plug includes a top portion and a bottom portion below the top portion, in which the bottom portion of the contact plug extends into the first source/drain structure. A first spacer structure is along a sidewall of the top portion of the contact plug. A second spacer structure is along a sidewall of the bottom portion of the contact plug, in which the first spacer structure is thicker than the second spacer structure.

In some embodiments, the first spacer structure comprises more layers than the second spacer structure.

In some embodiments, the first spacer structure includes a first spacer layer, and a second spacer layer between the first spacer layer and the contact plug.

In some embodiments, the second spacer structure is in contact with the second source/drain structure.

In some embodiments, the semiconductor device further includes a first isolation structure laterally surrounding the first source/drain structure, and a second isolation structure over the first isolation structure and laterally surrounding the second source/drain structure, in which the first spacer structure is between the second isolation structure and the top portion of the contact plug.

In some embodiments, the second spacer structure is in contact with the first isolation structure and the second isolation structure.

In some embodiments, the semiconductor device further includes a first silicide layer between the first source/drain structure and the bottom portion of the contact plug, in which the first silicide layer covers at least a sidewall and a bottom surface of the bottom portion of the contact plug.

In some embodiments, the semiconductor device further includes a second silicide layer between the second source/drain structure and a bottom surface of the top portion of the contact plug.

In some embodiments of the present disclosure, a method includes forming a device over a substrate and comprising a first transistor and a second transistor vertically above the first transistor, in which first source/drain structure of the first transistor is covered by a first isolation structure and a second source/drain structure of the second transistor is covered by a second isolation structure; forming a first opening in the second isolation structure and exposing the second source/drain structure; forming a first spacer layer lining the first opening; after forming the first spacer layer, forming a second opening in the first and second isolation structures and exposing the first source/drain structure; forming a second spacer layer lining the first spacer layer and the second opening; performing an etching process to remove horizontal portions of the first spacer layer and the second spacer layer; and forming a contact plug in the first opening and the second opening.

In some embodiments, forming the second opening in the first and second isolation structures comprises forming a mask layer in the first opening; etching the first and second isolation structures through the mask layer to form the second opening; and removing the mask layer.

In some embodiments, the etching process is performed such that a recess is formed in the first source/drain structure.

In some embodiments, the etching process is performed to expose the first source/drain structure and the second source/drain structure.

In some embodiments, vertical portions of the first spacer layer and the second spacer layer remain on a sidewall of the first opening after the etching process is complete.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a first transistor over a substrate and comprising:
a first semiconductor layer;
a first source/drain structure in contact with on end of the first semiconductor layer; and
a first gate structure wrapping around the first semiconductor layer;
a second transistor vertically stacked above the first transistor and comprising:
a second semiconductor layer;
a second source/drain structure in contact with on end of the second semiconductor layer; and
a second gate structure wrapping around the second semiconductor layer;
a contact plug electrically connecting the first source/drain structure and the second source/drain structure, wherein the contact plug comprises a top portion and a bottom portion extending downward from a bottom surface of the top portion;
a dual-layer spacer structure along a sidewall of the top portion of the contact plug; and
a single-layer spacer structure along a sidewall of the bottom portion of the contact plug.

2. The semiconductor device of claim 1, wherein the dual-layer spacer structure comprises:
a first spacer layer; and
a second spacer layer between the first spacer layer and the sidewall of the top portion of the contact plug.

3. The semiconductor device of claim 2, wherein the second spacer layer and the single-layer spacer structure are made of a same material.

4. The semiconductor device of claim 2, wherein the first spacer layer is thicker than the second spacer layer.

5. The semiconductor device of claim 2, wherein the first spacer layer is in contact with the bottom surface of the top portion of the contact plug.

6. The semiconductor device of claim 1, wherein the dual-layer spacer structure is laterally spaced apart from the single-layer spacer structure.

7. The semiconductor device of claim 1, wherein the dual-layer spacer structure is thicker than the single-layer spacer structure.

8. A semiconductor device, comprising:
a first transistor over a substrate;
a second transistor vertically stacked above the first transistor;
a contact plug electrically connecting a first source/drain structure of the first transistor and a second source/drain structure of the second transistor, the contact plug comprising a top portion and a bottom portion below the top portion, wherein the bottom portion of the contact plug extends into the first source/drain structure;
a first spacer structure along a sidewall of the top portion of the contact plug; and
a second spacer structure along a sidewall of the bottom portion of the contact plug, wherein the first spacer structure is thicker than the second spacer structure.

9. The semiconductor device of claim 8, wherein the first spacer structure comprises more layers than the second spacer structure.

10. The semiconductor device of claim 8, wherein the first spacer structure comprises:
a first spacer layer; and
a second spacer layer between the first spacer layer and the contact plug.

11. The semiconductor device of claim 8, wherein the second spacer structure is in contact with the second source/drain structure.

12. The semiconductor device of claim 8, further comprising:
a first isolation structure laterally surrounding the first source/drain structure; and
a second isolation structure over the first isolation structure and laterally surrounding the second source/drain structure, wherein the first spacer structure is between the second isolation structure and the top portion of the contact plug.

13. The semiconductor device of claim 12, wherein the second spacer structure is in contact with the first isolation structure and the second isolation structure.

14. The semiconductor device of claim 8, further comprising a first silicide layer between the first source/drain structure and the bottom portion of the contact plug, wherein the first silicide layer covers at least a sidewall and a bottom surface of the bottom portion of the contact plug.

15. The semiconductor device of claim 14, further comprising a second silicide layer between the second source/drain structure and a bottom surface of the top portion of the contact plug.

16. A method, comprising:
forming a device over a substrate and comprising:
a first transistor, wherein a first source/drain structure of the first transistor is covered by a first isolation structure; and
a second transistor vertically above the first transistor, wherein a second source/drain structure of the second transistor is covered by a second isolation structure;
forming a first opening in the second isolation structure and exposing the second source/drain structure;
forming a first spacer layer lining the first opening;
after forming the first spacer layer, forming a second opening in the first and second isolation structures and exposing the first source/drain structure;
forming a second spacer layer lining the first spacer layer and the second opening;
performing an etching process to remove horizontal portions of the first spacer layer and the second spacer layer; and
forming a contact plug in the first opening and the second opening.

17. The method of claim 16, wherein forming the second opening in the first and second isolation structures comprises:
forming a mask layer in the first opening;
etching the first and second isolation structures through the mask layer to form the second opening; and
removing the mask layer.

18. The method of claim 16, wherein the etching process is performed such that a recess is formed in the first source/drain structure.

19. The method of claim 16, wherein the etching process is performed to expose the first source/drain structure and the second source/drain structure.

20. The method of claim 16, wherein vertical portions of the first spacer layer and the second spacer layer remain on a sidewall of the first opening after the etching process is complete.
